(19) United States
(12) Patent Application Publication
(10) Pub. No.: US 2012/0043989 A1
(43) Pub. Date: Feb. 23, 2012

(54) INSPECTION METHOD AND INSPECTION APPARATUS

(75) Inventors: Nobuyuki Shingai, Kanagawa (JP); Hiroshi Yamasaki, Kanagawa (JP)

(73) Assignee: Sony Corporation, Tokyo (JP)

(21) Appl. No.: 13/206,561

(22) Filed: Aug. 10, 2011

(30) Foreign Application Priority Data
Aug. 17, 2010 (JP) 2010-182429

(51) Int. Cl. G01R 31/26

(52) U.S. Cl. 324/761.01

(57) ABSTRACT

An inspection method, including: measuring an impedance of a cell structure of an inspection object that includes one or a plurality of serially-connected cell structures each including a transparent electrode layer formed on a substrate, a porous semiconductor layer formed on the transparent electrode layer, a porous insulator layer formed on the porous semiconductor layer, and a counter electrode layer formed on the porous insulator layer; and judging a quality of the inspection object based on the measured impedance of the cell structure.

### BACKGROUND

The present disclosure relates to an inspection method and apparatus for inspecting a quality of a dye-sensitized solar cell.

Dye-sensitized solar cells have a merit that they can be produced at lower costs than silicon-based solar cells that are currently a mainstream. Because of this merit, the dye-sensitized solar cells are attracting attentions as a next-generation solar cell that replaces the silicon-based solar cell, and various dye-sensitized solar cells are being proposed in recent years (see, for example, Japanese Patent Application Laid-open No. 2006-236960 (hereinafter, referred to as Patent Document 1) and Japanese Patent Application Laid-open No. 2009-110796 (hereinafter, referred to as Patent Document 2)).

As the dye-sensitized solar cell, a monolithic-type (see FIG. 1 of Patent Document 1 and FIG. 1 of Patent Document 2), W-type (see FIG. 7 of Patent Document 1), Z-type (see FIG. 8 of Patent Document 1), and face-type dye-sensitized solar cells are known.

As a method of inspecting a quality of the dye-sensitized solar cell, a method of inspecting a quality by irradiating sunlight or pseudo sunlight onto a dye-sensitized solar cell (finished product) and measuring photoelectric conversion characteristics is generally known.

### SUMMARY

However, in the case of the quality inspection method that uses the measurement of photoelectric conversion characteristics, while a quality of a dye-sensitized solar cell as a finished product can be inspected, it is difficult to inspect the quality of the dye-sensitized solar cell in a production process of the dye-sensitized solar cell.

Therefore, in the case of the inspection method above, while defective products can be prevented from reaching the market, production of defective products due to process fluctuations is difficult to be suppressed. As a result, there is a problem that the merit of the dye-sensitized solar cell that it can be produced at a low cost is not fully exerted.

In view of the circumstances as described above, there is a need for an inspection method and apparatus capable of inspecting a quality of a dye-sensitized solar cell in a production process of the dye-sensitized solar cell.

According to an embodiment of the present disclosure, there is provided an inspection method including measuring an impedance of a cell structure of an inspection object that includes one or a plurality of serially-connected cell structures each including a transparent electrode layer formed on a substrate, a porous semiconductor layer formed on the transparent electrode layer, a porous insulator layer formed on the porous semiconductor layer, and a counter electrode layer formed on the porous insulator layer.

A quality of the inspection object is judged based on the measured impedance of the cell structure.

By the inspection method, the quality of the dye-sensitized solar cell (inspection object) can be inspected during the production of a monolithic-type dye-sensitized solar cell. Accordingly, a quick feedback can be made with respect to a previous process in the production process, and a production of defective products due to process fluctuations can be suppressed. As a result, a yield can be improved, and cost cut is realized.

In the inspection method, the judgment on the quality of the inspection object may include comparing a standard impedance as an impedance of the cell structure, that is a criterion for the quality judgment, and the measured impedance of the cell structure, and judge that the inspection object is a non-defective product when a difference between the standard impedance and the impedance is equal to or smaller than a predetermined threshold value.

In the case of a monolithic-type dye-sensitized solar cell, in the cell structure, a dielectric layer constituted of the porous semiconductor layer and the porous insulator layer can be regarded as a capacitor interposed between the transparent electrode layer and the counter electrode layer. When there is a difference between a standard capacitance of a cell structure and a capacitance of the cell structure, a difference is caused between the standard impedance and the impedance. Therefore, the inspection object can be judged to be a non-defective product when the difference between the standard impedance and the impedance is equal to or smaller than the predetermined threshold value.

In the inspection method, the measurement of the impedance may include measuring two or more impedances of the cell structure using two or more different frequencies.

In this case, the judgment on the quality of the inspection object may include judging that the inspection object is a non-defective product when a difference between the two or more measured impedances is equal to or larger than a predetermined threshold value.

In the case of a cell structure in which a short circuit is not caused between the transparent electrode layer and counter electrode layer of the cell structure, the impedance decreases as the frequency increases. On the other hand, in a case where a short circuit is caused between the transparent electrode layer and counter electrode layer of the cell structure, there is a characteristic that the impedance becomes almost constant in a frequency range lower than a predetermined frequency (about 1 MHz).

This characteristic is used in the inspection method. Specifically, when the impedances of the cell structure are measured using two or more different frequencies and a difference between the two or more measured impedances is equal to or larger than a predetermined threshold value, it can be judged that a short circuit is not caused between the transparent electrode layer and the counter electrode layer (i.e., non-defective product).

In the inspection method, the measurement of the impedance may include measuring the impedance of the cell structure using a frequency of 10 Hz or more.

When the impedance of the cell structure is measured using a frequency of 10 Hz or less, the impedance of the cell structure becomes an impedance that depends on a particle interface of the porous semiconductor layer and the porous insulator layer. On the other hand, when the impedance of the cell structure is measured using a frequency of 10 Hz or more, the impedance of the cell structure becomes an impedance that depends on particles (bulk) of the porous semiconductor layer and the porous insulator layer.

Therefore, by measuring the impedance of the cell structure using the frequency of 10 Hz or more as described above, the impedance that depends on particles (bulk) of the porous semiconductor layer and the porous insulator layer can be measured.

In the inspection method, the measurement of the impedance may include measuring the impedance of the cell structure using a frequency of 1 kHz or more.

The impedance of the cell structure has characteristics that, when the impedance is measured using a frequency lower than 1 kHz, the impedance becomes high, a fluctuation with time is large, and the impedance is apt to be influenced by ambient light. In this case, the inspection of the inspection object becomes difficult.

On the other hand, the impedance of the cell structure has characteristics that, when the impedance is measured using a frequency of 1 kHz or more, the impedance is relatively small, there is hardly no fluctuation with time, and there is hardly no influence of ambient light. Therefore, by measuring the impedance of the cell structure using the frequency of 1 kHz or more, a stable quality inspection becomes possible.

In the inspection method, the measurement of the impedance may include measuring the impedance of the cell structure using a frequency that is 1 kHz or more and 1 MHz or less.

As described above, in the case of a cell structure in which a short circuit is not caused between the transparent electrode layer and counter electrode layer of the cell structure, the impedance decreases as the frequency increases. On the other hand, when a short circuit is caused between the transparent electrode layer and counter electrode layer of the cell structure, the impedance becomes almost constant within the frequency range smaller than 1 MHz.

When the impedance is measured using a frequency of 1 MHz or more, there is hardly no difference between the impedance of the cell structure in which a short circuit is not caused and the impedance of the cell structure in which a short circuit is caused. On the other hand, when the impedance is measured using a frequency of 1 MHz or less, since the impedance of the cell structure in which a short circuit is caused is constant, a difference is caused between the impedance of the cell structure in which a short circuit is not caused and the impedance of the cell structure in which a short circuit is caused. Therefore, by measuring the impedance of the cell structure using a frequency of 1 MHz or less, a short circuit of the cell structure can be inspected.

In the inspection method, the measurement of the impedance may include measuring the impedance of the cell structure using a frequency that is 1 kHz or more and 100 kHz or less.

When the impedance of the cell structure is measured using a frequency of 100 kHz or less, the difference between the impedance of the cell structure in which a short circuit is not caused and the impedance of the cell structure in which a short circuit is caused is large. Therefore, by measuring the impedance of the cell structure using a frequency of 100 kHz or less, larger short circuit resistance can be detected.

According to another embodiment of the present disclosure, there is provided an inspection method including bringing a conductor into contact with a porous semiconductor layer of an inspection object including a transparent electrode layer formed on a substrate and the porous semiconductor layer formed on the transparent electrode layer.

An impedance between the transparent electrode layer and the conductor is measured.

A quality of the inspection object is judged based on the measured impedance between the transparent electrode layer and the conductor.

By the inspection method, it becomes possible to measure the impedance of the cell structure of the inspection object and judge a quality of the inspection object based on the impedance in production processes of W-type, Z-type, and face-type dye-sensitized solar cells.

According to an embodiment of the present disclosure, there is provided an inspection apparatus including a measurement portion and a controller.

The measurement portion is configured to measure an impedance of a cell structure of an inspection object that includes one or a plurality of serially-connected cell structures each including a transparent electrode layer formed on a substrate, a porous semiconductor layer formed on the transparent electrode layer, a porous insulator layer formed on the porous semiconductor layer, and a counter electrode layer formed on the porous insulator layer.

The controller is configured to judge a quality of the inspection object based on the measured impedance of the cell structure.

According to another embodiment of the present disclosure, there is provided an inspection apparatus including a conductor, a measurement portion, and a controller.

The conductor is brought into contact with a porous semiconductor layer of an inspection object including a transparent electrode layer formed on a substrate and the porous semiconductor layer formed on the transparent electrode layer.

The measurement portion is configured to measure an impedance between the transparent electrode layer and the conductor while the conductor is in contact with the porous semiconductor layer.

The controller is configured to judge a quality of the inspection object based on the measured impedance between the transparent electrode layer and the conductor.

According to another embodiment of the present disclosure, there is provided an inspection method including measuring, by a measurement portion of an inspection apparatus, an impedance of a cell structure of an inspection object that includes one or a plurality of serially-connected cell structures each including a transparent electrode layer formed on a substrate, a porous semiconductor layer formed on the transparent electrode layer, a porous insulator layer formed on the porous semiconductor layer, and a counter electrode layer formed on the porous insulator layer.

A controller of the inspection apparatus judges a quality of the inspection object based on the measured impedance of the cell structure.

According to another embodiment of the present disclosure, there is provided an inspection method including measuring, by a measurement portion of an inspection apparatus, while a conductor is in contact with a porous semiconductor layer of an inspection object including a transparent electrode layer formed on a substrate and the porous semiconductor layer formed on the transparent electrode layer, an impedance between the transparent electrode layer and the conductor.

A controller of the inspection apparatus judges a quality of the inspection object based on the measured impedance between the transparent electrode layer and the conductor.

As described above, according to the embodiments of the present disclosure, an inspection method and apparatus capable of inspecting a quality of a dye-sensitized solar cell in a production process of the dye-sensitized solar cell can be provided.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a schematic plan view showing a dye-sensitized solar cell for which a quality is inspected by an inspection method according to an embodiment of the present disclosure;

FIG. 2 is a cross-sectional side view of the dye-sensitized solar cell;

FIG. 3 is a flowchart showing a production process of a dye-sensitized solar cell including the inspection method according to the embodiment of the present disclosure;

FIG. 4 is a side view of an inspection object;

FIG. 5 is a schematic diagram for explaining the inspection method according to the embodiment of the present disclosure;

FIG. 6 is a schematic diagram of a case where a cell structure of the inspection object is regarded as a flat-plate capacitor;

FIG. 7 is a diagram showing an impedance Z of a cell structure of an experimental inspection object;

FIG. 8 is a diagram showing an equivalent circuit of the cell structure of the inspection object;

FIG. 9 is a diagram showing, by a Nyquist diagram, results of performing an alternate impedance measurement on the cell structure of the inspection object using an impedance measurement device;

FIG. 10 is a diagram for explaining a difference between characteristics of the impedance Z in a case where the impedance Z of the cell structure of the inspection object is measured with a low frequency and characteristics of the impedance Z in a case where the impedance Z of the cell structure of the inspection object is measured with a high frequency;

FIG. 11 is a diagram showing an equivalent circuit of the cell structure in a case where a transparent electrode layer and a counter electrode layer are electrically short-circuited;

FIG. 12 is a Bode diagram showing a case where the impedance Z of the experimental inspection object in which a short circuit is caused between electrode layers is measured by the alternate impedance measurement;

FIG. 13 is a schematic diagram showing an inspection apparatus according to the embodiment of the present disclosure;

FIG. 14 is a cross-sectional side view of a Z-type dye-sensitized solar cell;

FIG. 15 is a flowchart showing a production process of a dye-sensitized solar cell including the inspection method according to another embodiment of the present disclosure;

FIG. 16 is a schematic diagram for explaining the inspection method according to another embodiment of the present disclosure; and

FIG. 17 is a schematic diagram showing the inspection apparatus according to another embodiment of the present disclosure.

### DETAILED DESCRIPTION OF EMBODIMENTS

Hereinafter, embodiments of the present disclosure will be described with reference to the drawings.

### First Embodiment

(Structure of Dye-Sensitized Solar Cell 100)

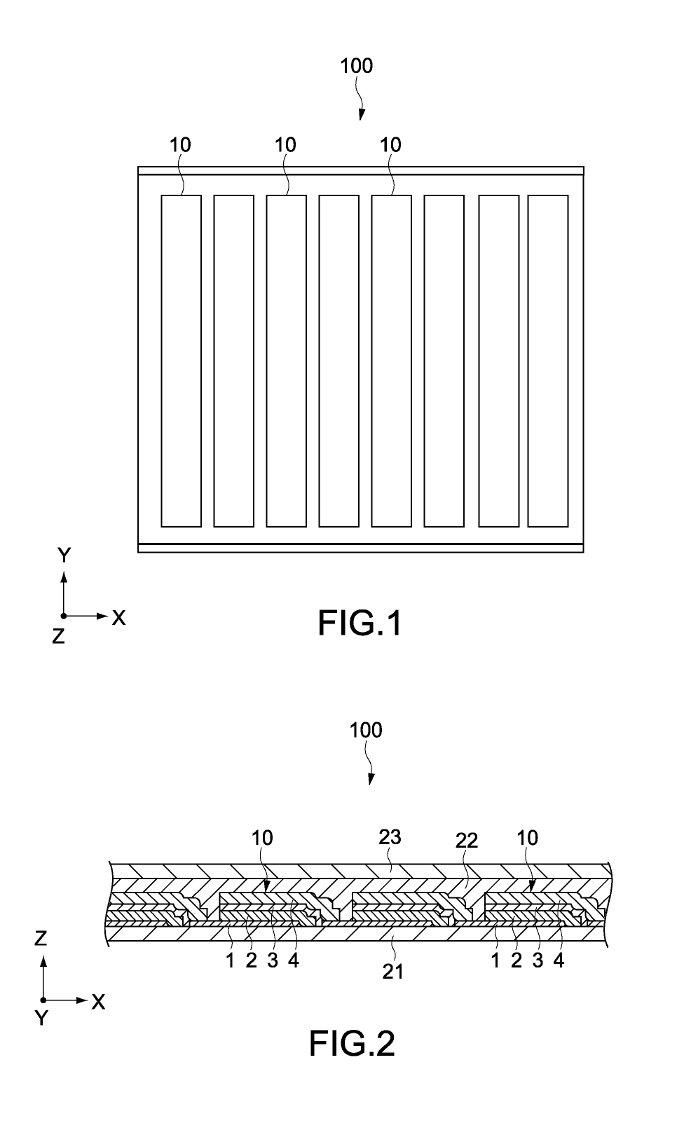

FIG. 1 is a schematic plan view showing a dye-sensitized solar cell 100 for which a quality is inspected by an inspection method according to a first embodiment of the present disclosure. FIG. 2 is a cross-sectional side view of the dye-sensitized solar cell 100.

As shown in the figures, the dye-sensitized solar cell 100 for which a quality is inspected by the inspection method of the first embodiment is a monolithic-type dye-sensitized solar cell 100.

The dye-sensitized solar cell 100 includes a transparent substrate 21 (substrate), a plurality of cell structures 10 formed on the transparent substrate 21, a sealing layer 22 that seals the cell structures 10, and an exterior member 23 formed on the sealing layer 22.

The transparent substrate 21 is constituted of, for example, a glass substrate or a transparent resin substrate formed of an acrylic resin or the like. As a material of the sealing layer 22, a resin such as an epoxy resin and a urethane resin, a fritted glass, and the like are used. As a material of the exterior member 23, a gas-barrier film structured by laminating a material having a high gas-barrier property, such as aluminum and alumina, and the like are used.

The cell structures 10 each have a cuboid shape that is elongated in one direction (Y-axis direction). The cell structures 10 are electrically connected in series in an X-axis direction. FIG. 1 shows an example where 8 cell structures 10 are connected in series. It should be noted that the number of cell structures 10 is not particularly limited. The cell structures 10 do not need to be provided plurally and may be provided singly.

The cell structure 10 includes a transparent electrode layer 1 formed on the transparent substrate 21, a porous semiconductor layer 2 formed on the transparent electrode layer 1, a porous insulator layer 3 formed on the porous semiconductor layer 2, and a counter electrode layer 4 formed on the porous insulator layer 3.

As a material of the transparent electrode layer 1, fluorine-doped SnO₂ (FTO), an iridium-tin composite oxide (ITO), and the like are used.

The porous semiconductor layer 2 has a porous structure including minute particles (e.g., several ten nm to several hundred nm) supporting a sensitizing dye. As a material of the porous semiconductor layer 2, a metal oxide such as titanium oxide is used, for example. As the sensitizing dye supported by the minute particles of the porous semiconductor layer 2, there are a metal complex such as a ruthenium complex and an iron complex and a colored dye such as eosin and rhodamine.

The porous insulator layer 3 also has a porous structure including minute particles (e.g., several ten nm to several hundred nm) like the porous semiconductor layer 2. For the porous insulator layer, an insulation material such as zirconia and alumina is used.

The porous semiconductor layer 2 and the porous insulator layer 3 include an electrolyte among the minute particles. As the electrolyte, methoxy acetonitrile, acetonitrile, ethylene carbonate, and the like are used. The electrolyte contains a redox pair. As the redox pair, iodine/iodide ion, bromine/bromide ion, and the like are used.

As a material of the counter electrode layer 4, fluorine-doped SnO₂ (FTO), an iridium-tin composite oxide (ITO), gold, platinum, carbon, and the like are used.

The counter electrode layer 4 is connected to the transparent electrode layer 1 of the adjacent cell structure 10. As a result, the plurality of cell structures 10 are connected in series.

It should be noted that the examples of the materials of the members constituting the dye-sensitized solar cell 100 are mere examples and can be changed as appropriate.

(Operation Principle of Dye-Sensitized Solar Cell 100)

Next, an operation principle of the dye-sensitized solar cell 100 will be described.

Light that has passed through and entered the transparent substrate 21 from the transparent substrate 21 side excites a sensitizing dye supported by the minute particles of the porous semiconductor layer 2 to generate electrons. The electrons move from the sensitizing dye to the minute particles of the porous semiconductor layer 2 and then move to the transparent electrode layer 1. On the other hand, the sensitizing dye that has lost the electrons receives electrons from the redox pair of the electrolyte included in the porous semiconductor layer 2 and the porous insulator layer 3. The redox pair that has lost the electrons moves to the counter electrode layer 4 side and receives electrons on the surface of the counter electrode layer 4. By the series of reactions, an impetus is generated between the transparent electrode layer 1 and the counter electrode layer 4.

When the dye-sensitized solar cell 100 includes a plurality of cell structures 10, an impetus of all of the plurality of cell structures 10 is generated between the transparent electrode layer 1 of the cell structure 10 at one end and the counter electrode layer 4 of the cell structure 10 at the other end.

(Production Method and Inspection Method for Dye-Sensitized Solar Cell 100)

Next, a production method and inspection method for the dye-sensitized solar cell 100 will be described.

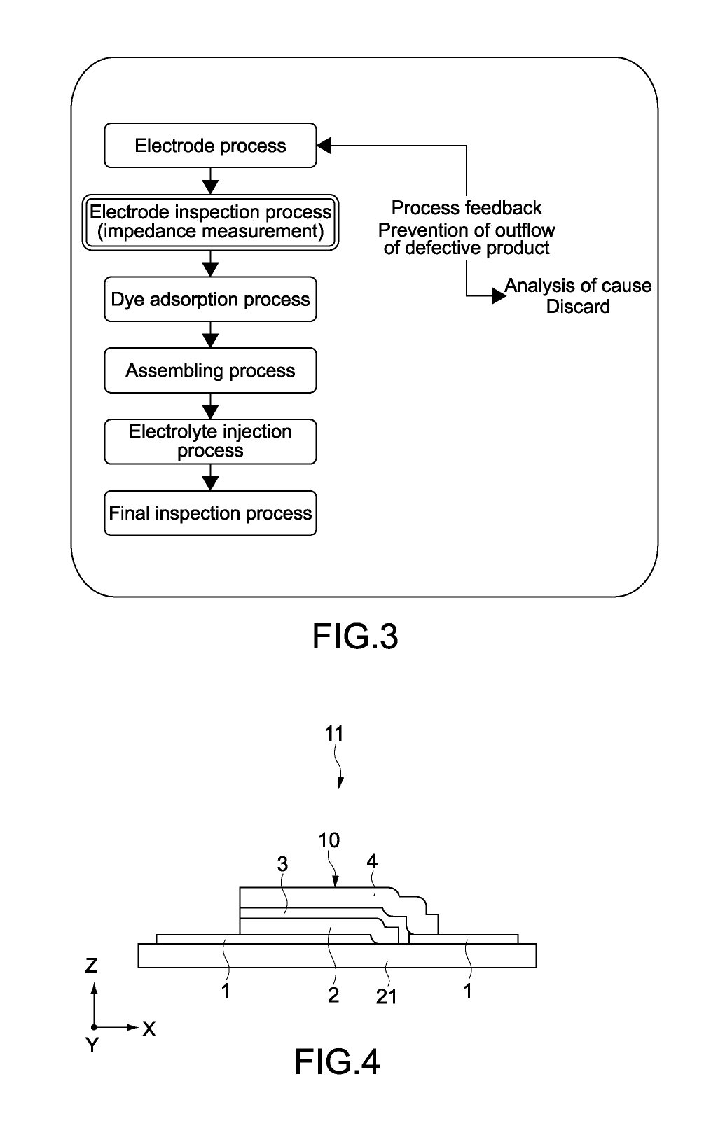

FIG. 3 is a flowchart showing a production process of a dye-sensitized solar cell including the inspection method according to the first embodiment of the present disclosure.

(Electrode Process)

In an electrode process, the transparent electrode layer 1 is formed on the entire surface of the transparent substrate 21 and patterned in stripes after that by etching. Next, the porous semiconductor layer 2 is printed on the transparent electrode layer 1 by screen printing and temporarily dried. After that, the porous semiconductor layer 2 is sintered. Then, the porous insulator layer 3 is printed on the porous semiconductor layer 2 by screen printing, temporarily dried, and sintered. Subsequently, the counter electrode layer 4 is printed on the porous insulator layer 3 by screen printing, temporarily dried, and sintered.

As a result, in the electrode process, one or a plurality of cell structures 10 are formed on the transparent substrate 21. It should be noted that in the descriptions on the first embodiment, the dye-sensitized solar cell 100 obtained after the electrode process, that is, the dye-sensitized solar cell 100 in which one or a plurality of cell structures 10 are formed on the transparent substrate 21, is referred to as inspection object 11 (see FIG. 4).

(Electrode Inspection Process)

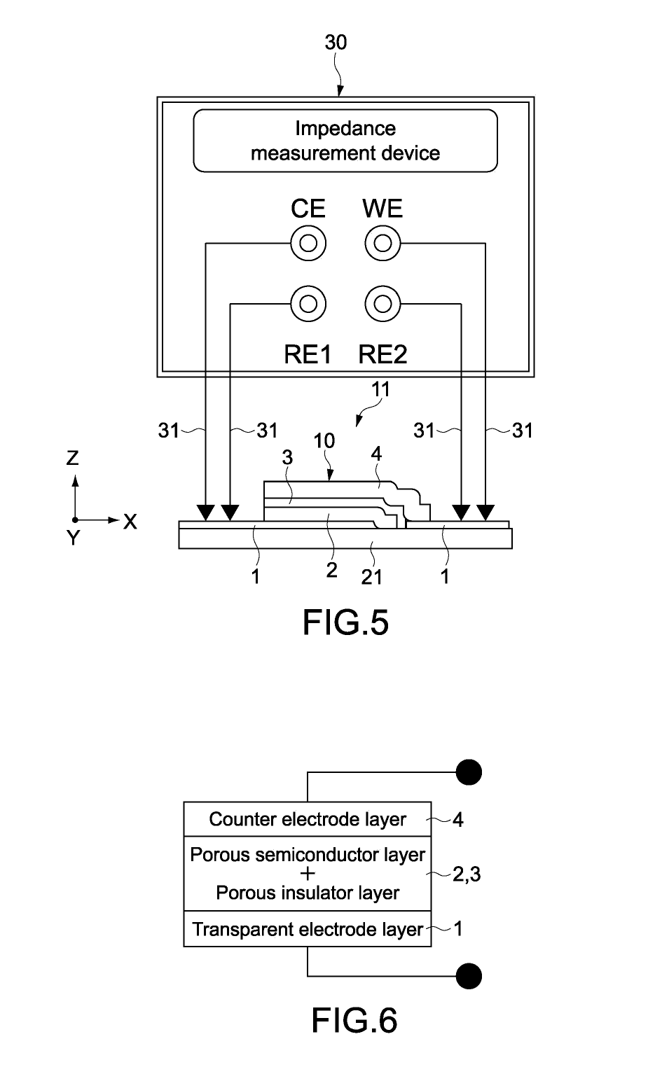

FIG. 4 is a side view of the inspection object 11. FIG. 5 is a schematic diagram for explaining the inspection method according to the first embodiment of the present disclosure.

As shown in FIG. 4, the inspection object 11 (dye-sensitized solar cell 100 obtained after electrode process) includes the transparent substrate 21 and (one or a plurality of) cell structures 10 formed on the transparent substrate 21. The cell structure 10 includes the transparent electrode layer 1, the porous semiconductor layer 2 (no sensitizing dye, no electrolyte), the porous insulator layer 3 (no electrolyte), and the counter electrode layer 4.

As shown in FIG. 5, in the electrode inspection process, an impedance Z of the cell structure 10 is measured by an alternate impedance measurement using an impedance measurement device 30. It should be noted that FIGS. 4 and 5 show a case where the number of cell structures 10 of the inspection object 11 is 1.

In the electrode inspection process, the inspection objects 11 are randomly inspected at a certain interval, or all of the inspection objects 11 are inspected.

The impedance measurement device 30 includes 4 terminals (CE, RE1, WE, RE2). Connected to the 4 terminals are probes 31. The probes 31 connected to the CE and RE1 terminals are brought into contact with one transparent electrode layer 1, and the probes 31 connected to WE and RE2 terminals are brought into contact with the other transparent electrode layer 1. Then, by a four-terminal method, the impedance Z of the cell structure 10 is measured.

As the impedance measurement device 30, an impedance measurement apparatus capable of freely sweeping a frequency, an LCR meter capable of measuring the impedance Z using several fixed measurement frequencies, and the like are used. Since the LCR meter is inexpensive, costs can be cut when using the LCR meter.

Although the case where a single cell structure 10 is provided is shown in FIG. 5, when the inspection object 11 includes a plurality of cell structures 10, the CE and RE1 terminals of the impedance measurement device 30 are brought into contact with the transparent electrode layer 1 of the cell structure 10 at one end, and the WE and RE2 terminals of the impedance measurement device 30 are brought into contact with the transparent electrode layer 1 connected to the counter electrode layer 4 of the cell structure 10 at the other end. Then, by the four-terminal method, the entire impedance Z of the plurality of serially-connected cell structures 10 is measured.

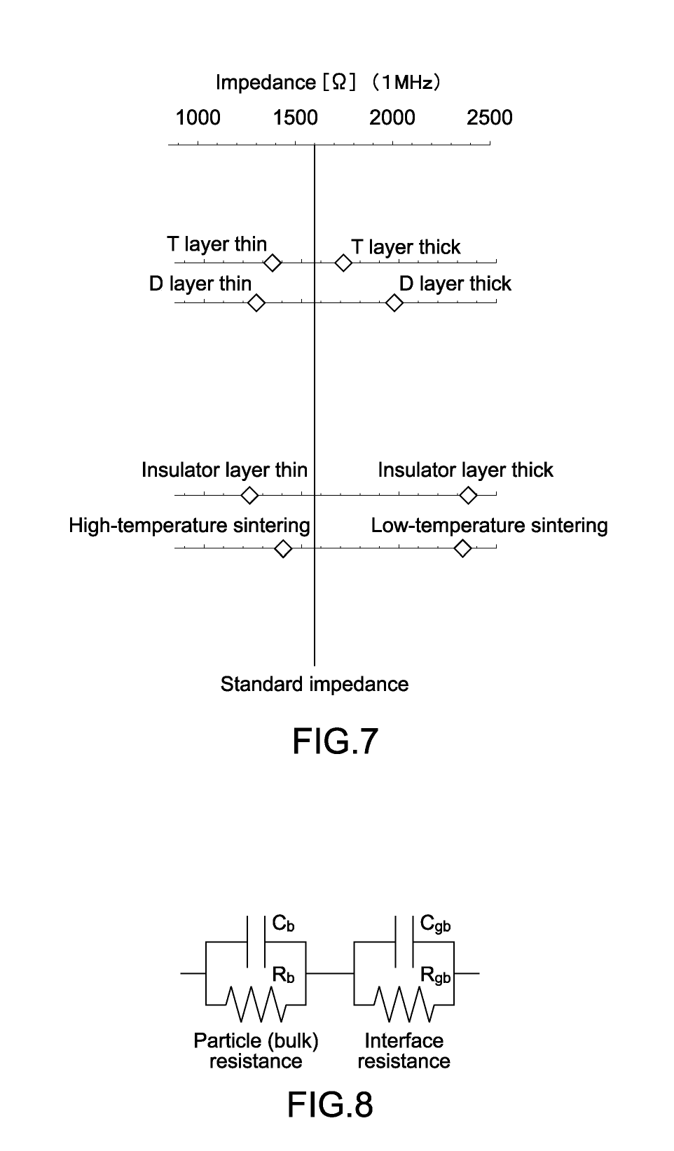

An operator judges a quality of the inspection object 11 based on the measured impedance Z. In this case, the operator judges the quality of the inspection object 11 by comparing a standard impedance Z′ (see FIG. 7) as an impedance of a cell structure 10 to be a criterion for the quality judgment (cell structure 10 as non-defective product) and the impedance Z of the cell structure 10 as the inspection object.

FIG. 6 is a schematic diagram of a case where the cell structure 10 of the inspection object 11 is regarded as a flat-plate capacitor.

As shown in FIG. 6, the cell structure 10 can be regarded as a flat-plate capacitor in which a dielectric body constituted of the porous semiconductor layer 2 and the porous insulator layer 3 is interposed between the transparent electrode layer 1 and the counter electrode layer 4.

A capacitance C of the flat-plate capacitor is represented by the following equation (1).

C=∈s*∈o*S/d (1)

where ∈s represents a relative permittivity, ∈o represents a dielectric constant in vacuum, S represents an area, and d represents thickness

Moreover, the impedance Z of the flat-plate capacitor is represented by the following equation (2).

Z=1/(j*Ω*C) (2)

In the electrode inspection process, the quality of the cell structure 10 of the inspection object 11 is judged using the relationships of the equations (1) and (2).

Specifically, when there is a difference between the standard impedance Z′ as an impedance of a standard (non-defective product) cell structure 10 and the impedance Z of the cell structure 10 as the inspection object, a difference in the capacitance C is caused between the standard cell structure 10 and the cell structure 10 as the inspection object. When there is a difference in the capacitance C between the standard cell structure 10 and the cell structure 10 as the inspection object, a difference is caused in any of the relative permittivity ∈s, the area S, and the thickness d between the standard cell structure 10 and the cell structure 10 as the inspection object.

Therefore, when there is a difference between the standard impedance Z′ as an impedance of the standard cell structure 10 and the impedance Z of the cell structure 10 as the inspection object, a difference is caused in any of the relative permittivity ∈s, the area S, and the thickness d between the standard cell structure 10 and the cell structure 10 as the inspection object.

Accordingly, by comparing the standard impedance Z′ of the standard cell structure 10 and the impedance Z of the cell structure 10 as the inspection object, the operator can detect a defect of the cell structure 10 that is due to a change in any of the relative permittivity ∈s, the area S, and the thickness d.

Here, in the electrode process, when positional deviations of the porous semiconductor layer 2, the porous insulator layer 3, and the counter electrode layer 4 during printing, fading in printing the counter electrode layer 4, peeling of the porous semiconductor layer 2, the porous insulator layer 3, and the counter electrode layer 4, and the like are caused, the area S changes with respect to the standard cell structure 10.

Further, in the electrode process, when a change in a paste viscosity of the layers 2 to 4 in printing, a change in a squeegee pressure of the layers in printing, abrasion of a printing plate, insufficient temporary drying of the layers, a change in a calcination temperature of the layers in calcination, and the like are caused, the thickness d changed with respect to the standard cell structure 10.

Furthermore, in the electrode process, when a molecule structure of the material used for the porous semiconductor layer 2 (e.g., titanium oxide) is changed (anatase, rutile), the relative permittivity ∈s changes with respect to the standard cell structure 10.

The inventors of the present disclosure have produced, for an experiment, an inspection object 11 including a porous semiconductor layer 2 and porous insulator layer 3 having thicknesses different from the standard and an inspection object 11 including a porous semiconductor layer 2 and porous insulator layer 3 formed at a calcination temperature different from a standard condition, and measured an impedance Z of a cell structure 10 of the inspection object 11 that has been produced for an experiment at a frequency of 1 MHz using the impedance measurement device 30. It should be noted that the porous semiconductor layer 2 of the inspection object 11 that has been produced for an experiment has a 2-layer structure including a T layer (Transparent layer) formed on the transparent electrode layer 1 and a D layer (Diffusion layer) formed on the T layer.

FIG. 7 is a diagram showing the impedance Z of the cell structure 10 of the experimental inspection object 11.

As shown in FIG. 7, in the case of the cell structure 10 including the porous semiconductor layer 2 (T layer, D layer) and porous insulator layer 3 having smaller thicknesses than those of the standard cell structure 10, the impedance Z becomes smaller than the standard impedance Z′ (about 1600Ω). This is considered to be because the capacitance C increases as the thickness d decreases, with the result that the impedance Z becomes small.

On the other hand, in the case of the cell structure 10 including the porous semiconductor layer 2 (T layer, D layer) and porous insulator layer 3 having smaller thicknesses than those of the standard cell structure 10, the impedance Z becomes larger than the standard impedance Z′. This is considered to be because the capacitance C decreases as the thickness d increases, with the result that the impedance Z becomes large.

Further, as shown in FIG. 7, when the calcination temperature of the porous semiconductor layer 2 and the porous insulator layer 3 is higher than a standard condition, the impedance Z of the cell structure 10 becomes smaller than the standard impedance Z′. This is considered to be because, when the calcination temperature of the porous semiconductor layer 2 and the porous insulator layer 3 is high, the thickness d decreases due to ash glaze. As a result, the capacitance C increases, and the impedance Z decreases.

On the other hand, when the calcination temperature of the porous semiconductor layer 2 and the porous insulator layer 3 is lower than the standard condition, the impedance Z of the cell structure 10 becomes larger than the standard impedance Z′. This is considered to be because, when the calcination temperature of the porous semiconductor layer 2 and the porous insulator layer 3 is low, the thickness d is kept large. As a result, the capacitance C becomes small, and the impedance Z becomes large.

In the electrode inspection process, the operator compares the standard impedance Z′ (about 1600Ω in FIG. 7) and the measured impedance Z. Then, the operator judges that the inspection object 11 is a non-defective product when a difference between the impedances Z is equal to or smaller than a predetermined threshold value (e.g., about ±20Ω). When judging as a non-defective product, the operator passes the inspection object 11 on to subsequent processes (dye adsorption process). It should be noted that since the inspection method of this embodiment is a nondestructive inspection, the inspection object 11 for which the quality has been inspected can be passed on to the subsequent processes.

On the other hand, when the difference exceeds the predetermined threshold value, the operator judges the inspection object 11 as a defective product. Then, the operator analyzes a cause of the defect and feeds back to the previous process (electrode process). It should be noted that when judging as a defective product, the operator discards the inspection object 11 and does not pass it on to processes subsequent to the electrode inspection process.

As described above, according to the inspection method of this embodiment, the impedance Z of the cell structure 10 of the inspection object 11 can be measured so that a quality of the inspection object 11 can be judged based on the impedance Z in the production process of the monolithic-type dye-sensitized solar cell 100. Accordingly, a quick feedback to the previous process in the production process becomes possible, and generation of a defective product due to process fluctuations can be suppressed. As a result, a yield can be improved, and cost cut can be realized.

(Measurement Frequency of Impedance Z)

Next, a measurement frequency of the impedance Z in the alternate impedance measurement will be described.

((Relationship of Particle (Bulk) Resistance and Interface Resistance with Measurement Frequency of Impedance Z))

First, a relationship of a particle resistance and interface resistance with a measurement frequency of the impedance Z will be described.

As described above, the porous semiconductor layer 2 and the porous insulator layer 3 each have a porous structure including minute particles (bulk) of several ten nm to several hundred nm.

FIG. 8 is a diagram showing an equivalent circuit of the cell structure 10 of the inspection object 11.

As shown in FIG. 8, a particle (bulk) resistance of the porous semiconductor layer 2 and the porous insulator layer 3 can be regarded as a parallel circuit of a resistance component Rb and a capacitance component Cb. In addition, an interface resistance of particle interfaces of the porous semiconductor layer 2 and the porous insulator layer 3 can be regarded as a parallel circuit of a resistance component Rgb and a capacitance component Cgb. Moreover, the equivalent circuit of the cell structure 10 can be regarded as a circuit in which the parallel circuits are connected in series.

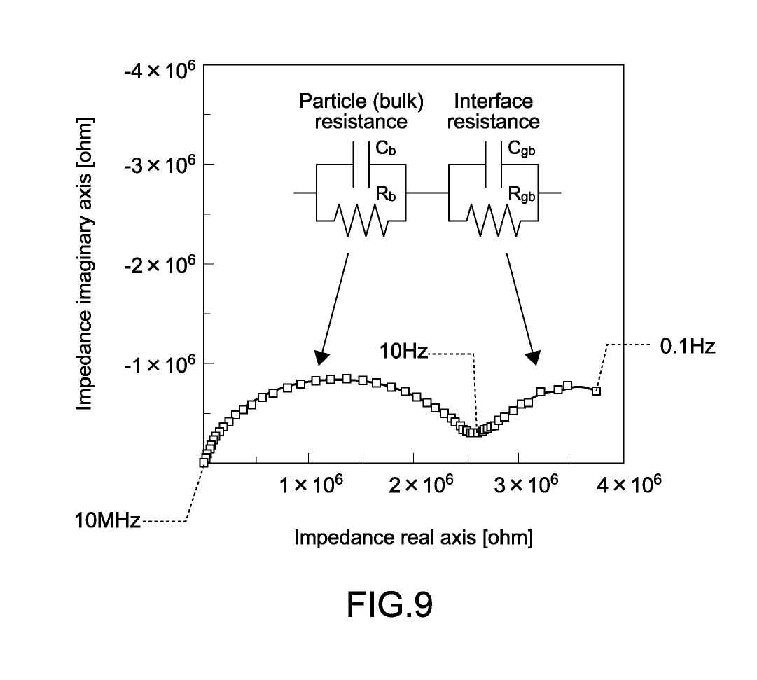

FIG. 9 is a diagram showing, by a Nyquist diagram, results of performing the alternate impedance measurement on the cell structure 10 of the inspection object 11 using the impedance measurement device 30.

As shown in FIG. 9, the Nyquist diagram is split into two mountains with 10 Hz as a boundary. The inventors of the present disclosure obtained a value of the capacitance C by fitting using the equivalent circuit based on the measured data. As a result, it was found that the capacitance C obtained from the relative permittivity ∈s, area S, and thickness d of the porous semiconductor layer 2 and the porous insulator layer 3 matches the mountain on the left-hand side. Therefore, it can be said that the impedance Z of the cell structure 10 at a frequency of 10 Hz or more depends on the particle resistance, and the impedance Z of the cell structure 10 at a frequency smaller than 10 Hz depends on the interface resistance.

Therefore, in the electrode inspection process, by measuring the impedance Z of the cell structure 10 of the inspection object 11 at a frequency of 10 Hz or more, the impedance Z that depends on the particles (bulk) of the porous semiconductor layer 2 and the porous insulator layer 3 can be measured.

((Difference Between Characteristics of Impedance Z of Cell Structure 10 of Inspection Object 11 when Impedance Z is Measured at Low Frequency and Characteristics of Impedance Z of Cell Structure 10 of Inspection Object 11 when Impedance Z is Measured at High Frequency))

Next, a difference between characteristics of the impedance Z of the cell structure 10 of the inspection object 11 when the impedance Z is measured at a low frequency and characteristics of the impedance Z of the cell structure 10 of the inspection object 11 when the impedance Z is measured at a high frequency will be described.

First, as a comparative example, a case where a quality of the inspection object 11 (dye-sensitized solar cell 100 subjected to electrode process) is inspected by a DC resistance measurement will be described.

When a quality of the inspection object 11 is inspected, a method of inspecting a quality of the inspection object 11 by the DC resistance measurement is also possible. In this regard, the inventors of the present disclosure measured a DC resistance value of the cell structure 10 of the inspection object 11 by the DC resistance measurement.

In this case, since the DC resistance value of the cell structure 10 of the inspection object 11 is as high as 10 MΩ or more, there is a problem that measurement accuracy is difficult to be secured with the DC resistance measurement using an existing DC resistance measurement device.

In the case of the DC resistance measurement, it has also become apparent that the DC resistance value largely changes depending on a measurement environment and the DC resistance value gradually changes with time. The reason why such a phenomenon occurs is considered to be because the porous semiconductor layer 2 has optical semiconductor characteristics and the porous semiconductor layer 2 and the porous insulator layer 3 have moisture sensitivity due to their porous structures. In actuality, a coefficient of fluctuation of the DC resistance value is 50% or more in 10 minutes, and the DC resistance value did not become stable just in an hour or so.

Next, a case where the impedance Z of the cell structure 10 of the inspection object 11 is measured by an alternate impedance measurement will be described.

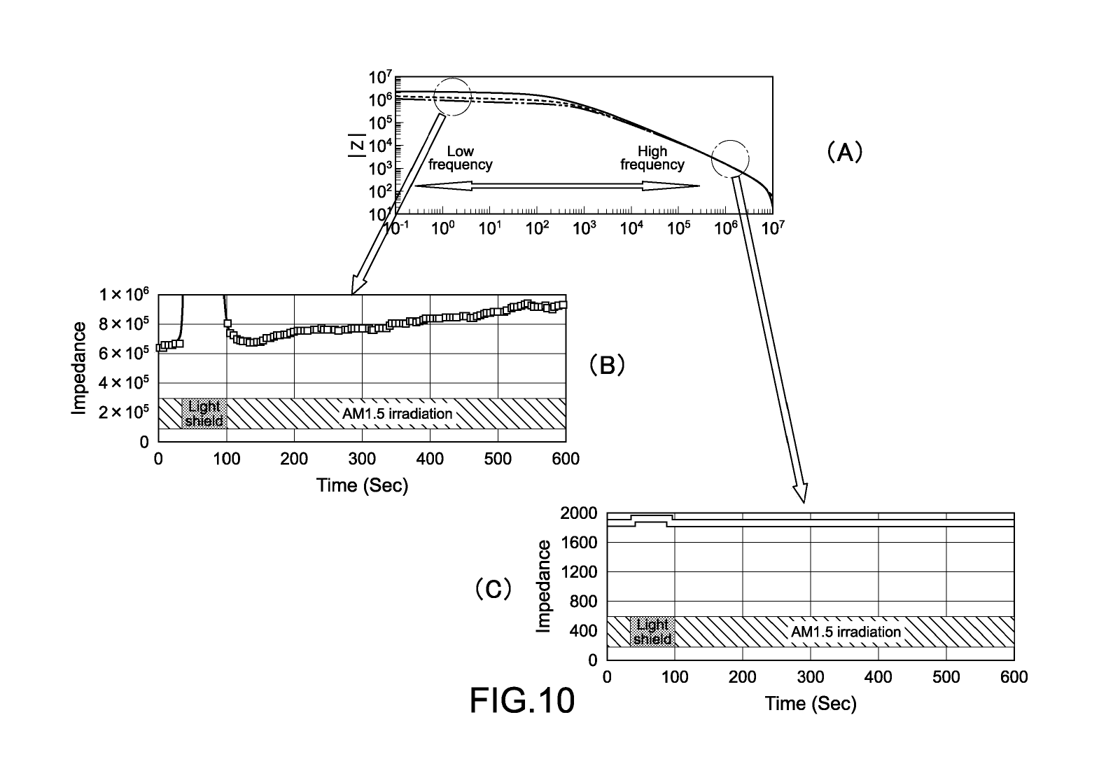

FIG. 10 is a diagram for explaining a difference between characteristics of the impedance Z of the cell structure 10 of the inspection object 11 in a case where the impedance Z is measured at a low frequency and characteristics of the impedance Z of the cell structure 10 of the inspection object 11 in a case where the impedance Z is measured at a high frequency.

A part A of FIG. 10 shows a relationship between a measurement frequency of the impedance Z and the impedance Z (absolute value). A part B of FIG. 10 shows a change of the impedance Z of the cell structure 10 of the inspection object 11 in 10 minutes in a case where the impedance Z is measured at 1 Hz. A part C of FIG. 10 shows a change of the impedance Z of the cell structure 10 of the inspection object 11 in 10 minutes in a case where the impedance Z is measured at 1 MHz.

It should be noted that in parts B and C of FIG. 10, the impedance Z is measured while pseudo sunlight of AM1.5 is irradiated onto the inspection object 11, and the impedance Z is measured while the pseudo sunlight is blocked from 30 s to 10 s for evaluating an influence of ambient light.

As shown in the part A of FIG. 10, it can be seen that, when the measurement frequency of the impedance Z is as low as below 1 kHz, the impedance Z of the cell structure 10 of the inspection object 11 takes a value near 1 MΩ, which is high.

As shown in the part B of FIG. 10, it can also be seen that, when the impedance Z of the cell structure 10 of the inspection object 11 is measured at a low frequency below 1 kHz (1 Hz), the impedance Z largely fluctuates with time. In the example shown in the part B of FIG. 10, the change rate of the impedance Z in 10 minutes is +47%.

In addition, as shown in the part B of FIG. 10, it can also be seen that, when the impedance Z of the cell structure 10 of the inspection object 11 is measured at a low frequency below 1 kHz (1 Hz), the impedance Z largely fluctuates at a time pseudo sunlight is blocked between 30 s to 100 s. In other words, it can be seen that in the impedance measurement at a low frequency, the impedance is apt to be influenced by ambient light.

As described above, in the case of the alternate impedance measurement at a low frequency below 1 kHz, there are characteristics that the impedance Z of the cell structure 10 of the inspection object 11 is high, the impedance Z largely fluctuates with time, and the impedance Z is apt to be influenced by ambient light. These characteristics coincide with the characteristics of the DC resistance value in the DC resistance measurement.

On the other hand, as shown in the part A of FIG. 10, it can be seen that, when the measurement frequency of the impedance Z is as high as 1 kHz or more, the impedance Z of the cell structure 10 of the inspection object 11 decreases as the frequency increases.

As shown in the part C of FIG. 10, it can also be seen that, when the measurement frequency of the impedance Z is as high as 1 kHz or more (1 MHz), the impedance Z hardly fluctuates with time. In the example shown in the part C of FIG. 10, the change rate of the impedance Z in 10 minutes is +0.3%.

In addition, as shown in the part C of FIG. 10, it can also be seen that, when the measurement frequency of the impedance Z is as high as 1 kHz or more (1 MHz), the impedance Z hardly fluctuates at a time pseudo sunlight is blocked between 30 s to 100 s.

In other words, when the measurement frequency of the impedance Z is as high as 1 kHz or more, there are characteristics that the impedance Z of the cell structure 10 of the inspection object 11 is relatively small, the impedance Z hardly fluctuates with time, and the impedance Z is hardly influenced by ambient light.

Therefore, by measuring the impedance Z of the cell structure 10 at a frequency or 1 kHz or more, the measured impedance Z becomes relatively small, and a fluctuation of the impedance Z with time and a fluctuation of the impedance Z due to ambient light can be eliminated. Accordingly, in the electrode inspection process, by measuring the impedance Z at a frequency of 1 kHz or more, it becomes possible to perform a stable quality inspection of the inspection object 11 with high accuracy. It should be noted that since an impedance measurement of 10 Hz or more becomes possible when the measurement frequency of the impedance Z is 1 kHz or more, the impedance Z that depends on the particles (bulk) of the porous semiconductor layer 2 and the porous insulator layer 3 as described above can be measured.

Here, when considering the cell structure 10 of the inspection object 11 by the equivalent circuit shown in FIG. 8, the impedance Z of the cell structure 10 depends on the resistance component at a low frequency and depends on the capacitance component at a high frequency. From such a relationship and the results of the parts B and C of FIG. 10, it can be said that the resistance component largely fluctuates with time and by ambient light, and the capacitance component is relatively stable without fluctuating so much with time and by ambient light. Specifically, the reason why the impedance Z is stable when measured at a high frequency of 1 kHz or more is because the resistance component that is apt to be influenced by time and ambient light is eliminated, and it has become possible to carry out an impedance Z measurement specializing in the capacitance component that is hardly influenced by time and ambient light.

(Dye Adsorption Process to Final Inspection Process)

Referring back to FIG. 3, in a dye adsorption process after the electrode inspection process, the inspection object 11 is immersed in a dye solution. As a result, the sensitizing dye is supported by minute particles of the porous semiconductor layer 2.

In the next assembling process, the sealing layer 22 is formed by being applied onto the cell structure 10. Then, the exterior member 23 is bonded to the sealing layer 22.

In the next electrolyte injection process, an electrolyte containing a redox pair is injected via an inlet (not shown) provided in a dye-sensitized cell in advance. The inlet is provided in each cell structure 10. When the electrolyte is injected, the electrolyte is injected among particles of the porous semiconductor layer 2 and the porous insulator layer 3 to fill the spaces among the minute particles. After that, the inlet is sealed.

In the next final inspection process, photoelectric conversion characteristics and the like of the dye-sensitized solar cell 100 (finished product) are inspected by sunlight, pseudo sunlight generated by solar simulator, or the like.

### Second Embodiment

Next, a second embodiment of the present disclosure will be described. It should be noted that in the descriptions on the second and subsequent embodiments, descriptions on components having the same structures and functions as those of the first embodiment will be simplified or omitted.

In the second embodiment, a detection of a short circuit of the cell structure 10 will be described.

In the electrode process (see FIG. 3), when some kind of a foreign substance is stuck between the transparent electrode layer 1 and the counter electrode layer 4, a failure in which an electrical short circuit is caused between the transparent electrode layer 1 and the counter electrode layer 4 may occur.

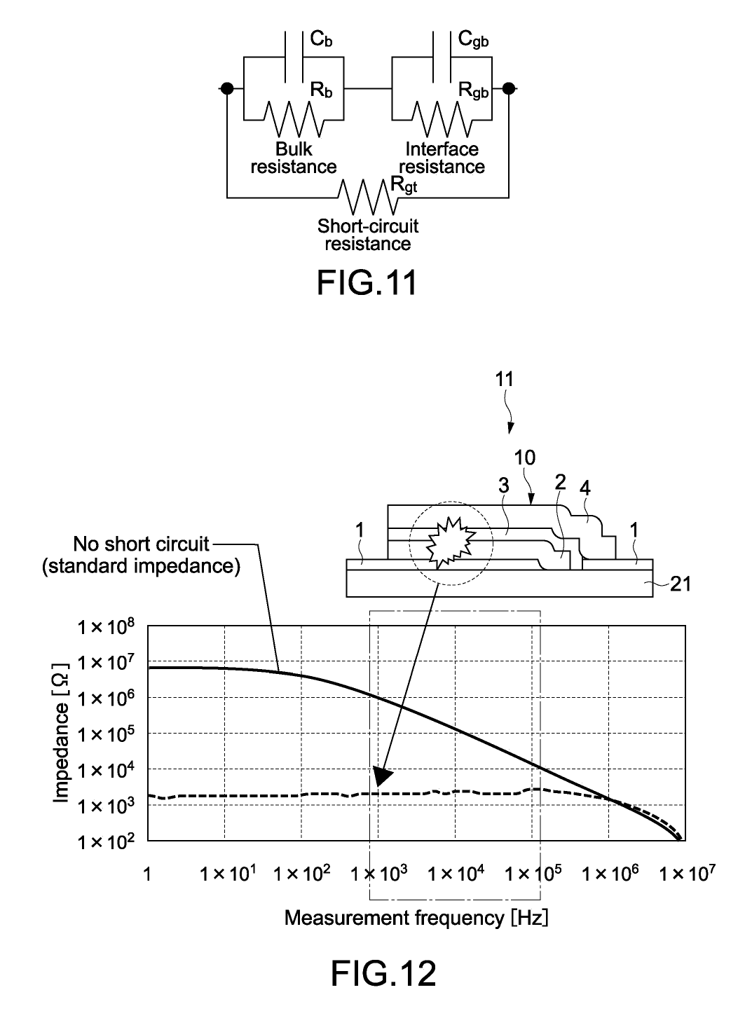

FIG. 11 is a diagram showing an equivalent circuit of the cell structure 10 in a case where the transparent electrode layer 1 and the counter electrode layer 4 are electrically short-circuited.

Here, as a comparative example, a case where a short circuit between the transparent electrode layer 1 and the counter electrode layer 4 is detected by a DC resistance measurement will be described.

Assuming a case where the inspection object 11 (dye-sensitized solar cell 100 subjected to electrode process) includes one cell structure 10 and a short-circuit resistance Rgt is sufficiently smaller than a combined resistance generated by the serial connection of the bulk resistance and the interface resistance, while the DC resistance value of the inspection object 11 (1 cell) in which a short circuit is not caused is, for example, a several-ten-MΩ order, the DC resistance value of the inspection object 11 (1 cell) in which a short circuit is caused is, for example, a several-kΩ order. Therefore, in such a case, a short circuit can be detected in the DC resistance measurement.

However, when the inspection object 11 includes a plurality of cell structures 10 or the short-circuit resistance Rgt is not sufficiently smaller than the combined resistance generated by the serial connection of the bulk resistance and the interface resistance, it is difficult to detect a short circuit by the DC resistance measurement.

For example, a case where a short circuit of an inspection object 11 including 8 cell structures 10 is to be detected by the DC resistance measurement is assumed. In this case, it is assumed that an inter-electrode short circuit is caused in one of the 8 cell structures 10 and the DC resistance value of the cell structure 10 in which the short circuit is caused has become 0.

The DC resistance value of all the 8 cell structures 10 including the cell structure 10 in which the short circuit is caused (DC resistance value=0) drops as compared to the DC resistance value obtained when no short circuit is caused in any of the 8 cell structures 10. However, the lowering rate is ⅛=12.5%, which is smaller than the fluctuation rate of the DC resistance value (50% or more in 10 minutes) that is due to, for example, moisture sensitivity of the porous semiconductor layer 2 and the porous insulator layer 3. As described above, since the lowering rate is smaller than the fluctuation rate of the DC resistance value, there is a problem that it is difficult to detect a short circuit of one of the plurality of cell structures 10.

Next, a quality inspection method for the dye-sensitized solar cell 100 according to the second embodiment will be described in detail.

The inventors of the present disclosure produced, as the experimental inspection object 11, an inspection object 11 having a 1-cell structure in which the transparent electrode layer 1 and the counter electrode layer 4 are short-circuited.

FIG. 12 is a Bode diagram showing a case where the impedance Z of the experimental inspection object 11 is measured by an alternate impedance measurement. It should be noted that FIG. 12 also shows a measurement result of the impedance Z of the inspection object 11 having a 1-cell structure in which a short circuit is not caused.

As shown in FIG. 12, when the measurement frequency of the impedance Z exceeds 1 MHz, there is almost no difference between the impedance Z of the cell structure 10 in which an inter-electrode short circuit is caused and the impedance Z of the cell structure 10 in which a short circuit is not caused (standard impedance Z′).

On the other hand, when the measurement frequency is 1 MHz or less, the short-circuit resistance Rgt becomes constant in the inspection object 11 in which an inter-electrode short circuit is caused, with the result that a difference is caused between the inspection object 11 in which an inter-electrode short circuit is caused and the inspection object 11 in which a short circuit is not caused. As described above, since a difference is caused between the inspection object 11 in which a short circuit is caused and the inspection object 11 in which a short circuit is not caused when the measurement frequency is 1 MHz or less, a short circuit can be detected by measuring the impedance Z of the inspection object 11 at a frequency of 1 MHz or less.

In this case, the operator measures the impedance Z of the inspection object 11 including one or a plurality of cell structures 10 at a frequency of 1 MHz or less in the electrode process. Then, the operator compares the measured impedance Z with the standard impedance Z′ of the inspection object 11 in which a short circuit is not caused (inspection object 11 as non-defective product).

The operator judges that the inspection object 11 is a non-defective product, that is, a short circuit is not caused, when a difference between the impedance Z and the standard impedance Z′ is equal to or smaller than a predetermined threshold value and passes the inspection object 11 on to the subsequent process. On the other hand, when the difference exceeds the predetermined threshold value, the operator judges that the inspection object 11 is a defective product, that is, a short circuit is caused, and does not pass it on to the subsequent process.

Here, as described above, when the measurement frequency of the impedance Z is as low as below 1 kHz, the impedance Z has characteristics that it largely fluctuates with time and is apt to be influenced by ambient light similar to the DC resistance value in the DC resistance measurement. On the other hand, when the measurement frequency of the impedance Z is 1 kHz or more, the impedance Z has characteristics that it hardly fluctuates with time and is hardly influenced by ambient light.

Therefore, the measurement frequency of the impedance Z is typically 1 kHz or more (1 MHz or less). By the alternate impedance measurement at 1 kHz or more, a short circuit of the cell structure 10 of the inspection object 11 can be appropriately detected while eliminating the fluctuation with time and influence of ambient light.

In this case, since a stable measurement of the impedance Z becomes possible, a detection of a short circuit of one of a plurality of cell structures 10, that has been difficult in the DC resistance measurement, can be carried out with ease.

On the other hand, as described above, since a difference in the impedance Z is caused between the case where a short circuit is caused and the case where a short circuit is not caused when the measurement frequency of the impedance Z is 1 MHz or less, a short circuit can be detected. It should be noted that when the measurement frequency of the impedance Z is near 1 MHz, a difference in the impedance Z between the case where a short circuit is caused and the case where a short circuit is not caused is small. When the difference in the impedance Z is small, the value of the short-circuit resistance that can be detected becomes small.

Therefore, when considering the detection of a larger short-circuit resistance, the measurement frequency of the impedance Z is typically (1 kHz or more and) 100 kHz or less.

### Modified Example of Second Embodiment

The example above has described the method of detecting a short circuit of a cell structure 10 by comparing the measured impedance Z and the standard impedance Z′ as an impedance of the cell structure 10 in which a short circuit is not caused. However, a short circuit of the cell structure 10 can be detected by other methods.

As shown in FIG. 12, in the case of the cell structure 10 in which a short circuit is not caused between the transparent electrode layer 1 and the counter electrode layer 4, the impedance Z decreases as the frequency increases. On the other hand, when a short circuit is caused between the transparent electrode layer 1 and the counter electrode layer 4 of the cell structure 10, the impedance Z has characteristics that it becomes almost constant at a frequency range lower than 1 MHz.

Specifically, at a frequency of 1 MHz or less, the impedance Z of the cell structure 10 in which a short circuit is not caused has characteristics that a difference in the impedance Z between two points having different frequencies is larger than that in the cell structure 10 in which a short circuit is caused. Conversely, the cell structure 10 in which a short circuit is caused has characteristics that there is almost no difference in the impedance Z between two points having different frequencies as compared to the cell structure 10 in which a short circuit is not caused.

By using such a relationship, a short circuit of the cell structure 10 can be detected.

In this case, the operator measures the impedance Z of the cell structure 10 at two or more different frequencies of 1 MHz or less in the electrode process. Then, the operator judges that a short circuit is not caused in the inspection object, that is, the inspection object is a non-defective product, when a difference between the two or more measured impedances Z is equal to or larger than a predetermined threshold value, and passes it on to the subsequent process.

On the other hand, when the difference between the two or more measured impedances Z is smaller than the predetermined threshold value, the operator judges that a short circuit is caused in the inspection object, that is, the inspection object is a defective product, and does not pass it on to the subsequent process.

Also by the method as described above, a short circuit of the cell structure 10 can be detected appropriately.

### Third Embodiment

Next, a third embodiment of the present disclosure will be described.

The above embodiments have described the case where the operator measures the impedance Z of the inspection object 11 using the impedance measurement device 30 to judge a quality of the inspection object 11 based on the measurement result. In other words, the quality inspection method for the inspection object 11 carried out by the operator has been described.

On the other hand, the quality inspection of the inspection object 11 can be automated. In the third embodiment, an inspection apparatus 40 that automatically measures the impedance Z of the inspection object 11 and automatically judges a quality of the inspection object 11 based on the measurement result will be described.

(Structure of Inspection Apparatus 40)

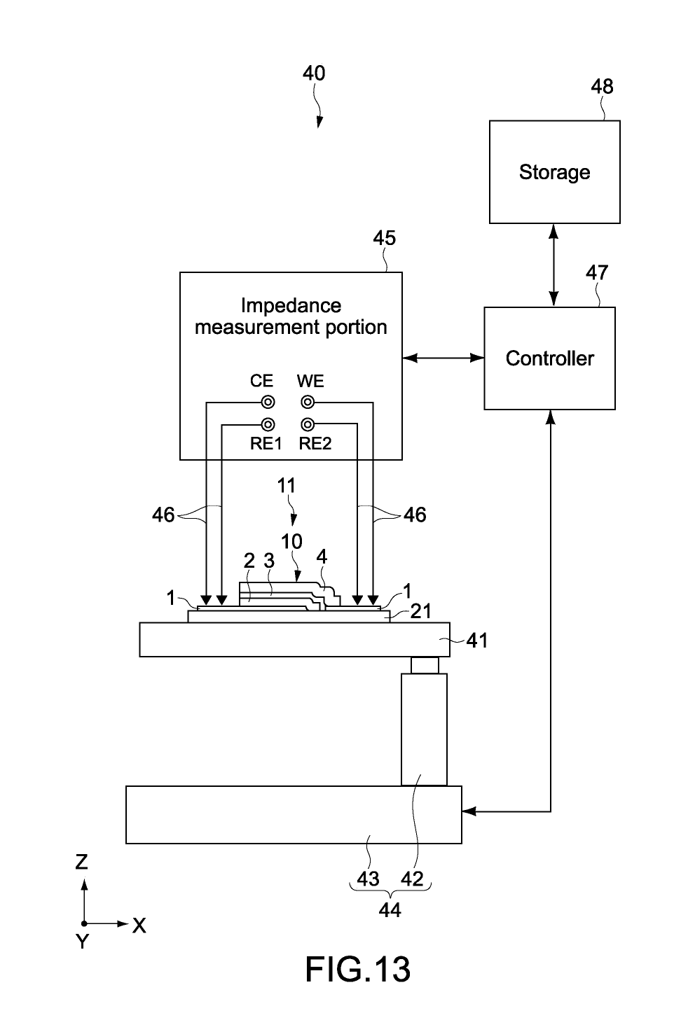

FIG. 13 is a schematic diagram showing the inspection apparatus 40.

As shown in FIG. 13, the inspection apparatus 40 includes a mounting table 41 on which the inspection object 11 is mounted, an XYZ stage 44 that moves the mounting table 41 in XYZ directions, and an impedance measurement portion 45 that measures the impedance Z of the cell structure 10 of the inspection object 11. The inspection apparatus 40 also includes a controller 47 that collectively controls the inspection apparatus 40 and a storage 48 that stores various programs necessary for control of the controller 47.

The XYZ stage 44 includes a lifting mechanism 42 that vertically moves the mounting table 41 and an XY stage 43 that moves the lifting mechanism 42 in the XY directions. For the lifting mechanism 42 and the XY stage 43, a fluid pressure cylinder, rack and pinion, belt and chain, a ball screw, and the like are used.

The impedance measurement portion 45 includes 4 terminals (CE, RE1, WE, RE2). Connected to the 4 terminals are probes 46. The probes 46 are each fixed at a predetermined position by a fixing member (not shown). As the impedance measurement portion 45, an impedance measurement apparatus capable of freely sweeping a frequency, an LCR meter capable of measuring the impedance Z at several fixed measurement frequencies, or the like is used.

The controller 47 is, for example, a CPU, and executes predetermined processing according to programs stored in the storage 48. For example, the controller 47 drives the XYZ stage 44 or judges a quality of the inspection object 11 based on the impedance Z of the inspection object 11 measured by the impedance measurement portion 45.

(Descriptions on Operation)

Next, an operation of the inspection apparatus 40 will be described.

First, the controller 47 of the inspection apparatus 40 drives the XY stage 43 to move the mounting table 41 in the XY directions, and moves the mounting table 41 to a pick-up position of the inspection object 11 (dye-sensitized solar cell 100 subjected to electrode process). Then, the inspection apparatus 40 receives the inspection object 11 from a supply apparatus (not shown) and mounts it on the mounting table 41.

Next, the controller 47 drives the XY stage 43 to move the mounting table 41 in the XY directions and moves the inspection object 11 to a measurement position of the impedance Z. Next, the controller 47 drives the lifting mechanism and moves the mounting table 41 upwardly. Accordingly, the probes 46 connected to the 4 terminals of the impedance measurement portion 45 come into contact with the transparent electrode layer 1 of the cell structure 10.

At this time, the probes 46 connected to the CE and RE1 terminals are brought into contact with one transparent electrode layer 1, and the probes 46 connected to the WE and RE2 terminals are brought into contact with the other transparent electrode layer 1. Then, by the 4-terminal method, the impedance Z of the cell structure 10 is measured at a predetermined frequency.

It should be noted that for the contact of the probes 46 with the transparent electrode layer 1 of the cell structure 10, a method of vertically moving the probes 46 may be used instead of the method of vertically moving the mounting table 41. Alternatively, a method of vertically moving both the mounting table 41 and the probes 46 may be used.

After the impedance Z is measured, the controller 47 calculates a difference between the measured impedance Z and the standard impedance Z′ (see FIGS. 7 and 12). Then, when the difference between the impedances Z is equal to or smaller than a predetermined threshold value, the controller 47 judges that the inspection object 11 is a non-defective product, that is, a positional deviation in printing, a short circuit, or the like is not caused in the inspection object 11. When judging as a non-defective product, the controller 47 drives the lifting mechanism 42 and the XY stage 43 and passes the inspection object 11 to a dye adsorption apparatus that executes dye adsorption processing in the next dye adsorption process.

On the other hand, when the difference exceeds the predetermined threshold value, the controller 47 judges that the inspection object 11 is a defective product, that is, a positional deviation in printing, a short circuit, or the like is caused in the inspection object 11. In this case, the controller 47 drives the lifting mechanism 42 and the XY stage 43 and discards the inspection object 11.

When the judgment is ended, the controller 47 stores the judgment result in the storage 48 and moves the mounting table 41 again to a handover position of the inspection object 11.

Since a quality of the inspection object 11 can be inspected automatically in the inspection apparatus 40, a 100% inspection of the inspection objects 11 can be executed with ease.

In the example above, the case where a quality of the inspection object 11 is judged based on the difference between the impedance Z measured by the impedance measurement portion 45 and the standard impedance Z′ has been described. However, the quality judgment method for the inspection object 11 is not limited thereto. As described above in the modified example of the second embodiment, the quality of the inspection object 11 may be judged based on the impedance Z of the inspection object 11 measured at two or more different frequencies.

In this case, the controller 47 controls the impedance measurement portion 45, measures the impedance Z of the inspection object 11 mounted on the mounting table 41 at two different frequencies, and calculates a difference between the two impedances. Then, the controller 47 judges that the inspection object 11 is a non-defective product, that is, a short circuit is not caused, when the difference between the two measured impedances Z is equal to or larger than a predetermined threshold value. In this case, the controller 47 drives the lifting mechanism 42 and the XY stage 43 and passes the inspection object 11 on to the dye adsorption apparatus that executes dye adsorption processing in the next dye adsorption process.

On the other hand, when the difference is smaller than the predetermined threshold value, the controller 47 judges that the inspection object 11 is a defective product, that is, a short circuit is caused. In this case, the controller 47 drives the lifting mechanism 42 and the XY stage 43 and discards the inspection object 11.

### Fourth Embodiment

Next, a fourth embodiment of the present disclosure will be described.

The above embodiments have described the method of inspecting a quality of the dye-sensitized solar cell 100 having a monolithic structure during a production process. On the other hand, the fourth embodiment describes a method of inspecting a quality of a dye-sensitized solar cell 200 having, for example, a Z-type, W-type, or face-type structure during a production process. It should be noted that out of the Z-type, W-type, and face-type dye-sensitized solar cells 200, the method of inspecting a quality of the Z-type dye-sensitized solar cell 200 will be described as a representative.

(Structure of Dye-Sensitized Solar Cell 200)

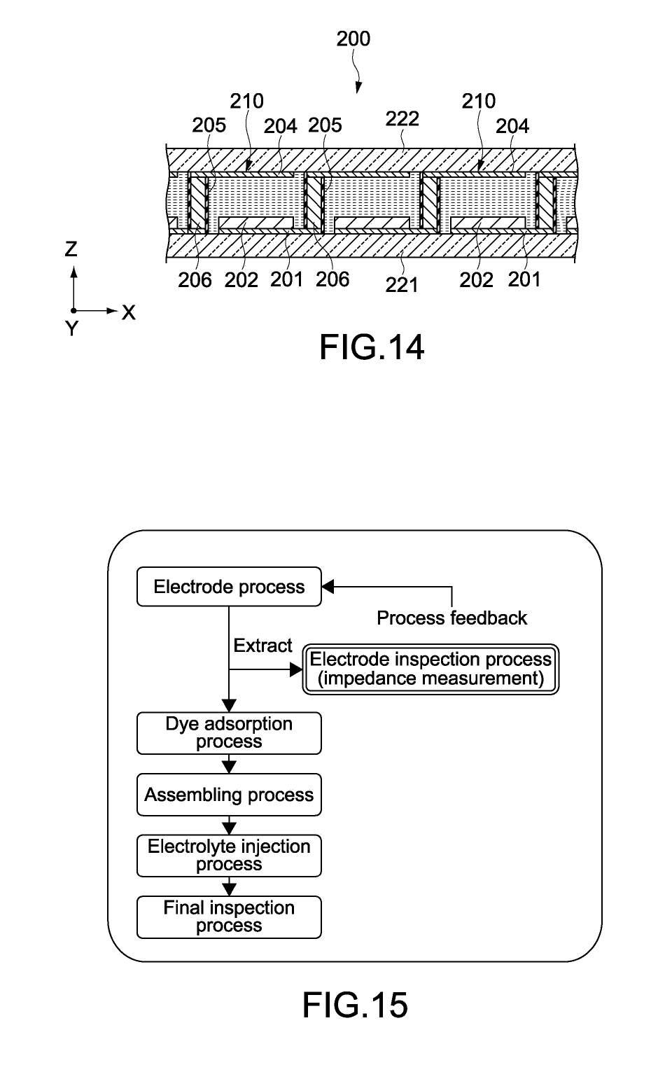

FIG. 14 is a cross-sectional side view of the Z-type dye-sensitized solar cell 200.

As shown in FIG. 14, the Z-type dye-sensitized solar cell 200 includes a transparent substrate 221, an opposing substrate 222, a plurality of cells 210 interposed between the transparent substrate 221 and the opposing substrate 222, and wall portions 205 for separating the cells 210.

The plurality of cells 210 each have a cuboid shape that is elongated in one direction (Y-axis direction) and are electrically connected in series in the X-axis direction. The cells 210 each include a transparent electrode layer 201 formed on the transparent substrate 221, a porous semiconductor layer 202 formed on the transparent electrode layer 201, and a counter electrode layer 204 formed on the opposing substrate 222 at a position opposing the porous semiconductor layer 202. The cells 210 each has an electrolyte including a redox pair inside.

The transparent electrode layer 201 is electrically connected to the counter electrode layer 204 of the adjacent cell 210 by a conductive member 206 provided inside each of the wall portions 205. As a result, the plurality of cells 210 are electrically connected in series.

(Production Method and Inspection Method for Dye-Sensitized Solar Cell 200)

FIG. 15 is a flowchart showing a production process of the dye-sensitized solar cell 200 including the inspection method of this embodiment.

(Electrode Process)

In an electrode process, the transparent electrode layer 201 is formed on the entire surface of the transparent substrate 221 and patterned in stripes after that by etching. Next, the porous semiconductor layer 202 is printed on the transparent electrode layer 201 by screen printing and temporarily dried. After that, the porous semiconductor layer 202 is sintered.

Then, the counter electrode layer 204 is printed on the opposing substrate 222 by screen printing, temporarily dried, and sintered. After that, the wall portion 205 having the conductive member 206 inside is formed on the counter electrode layer 204.

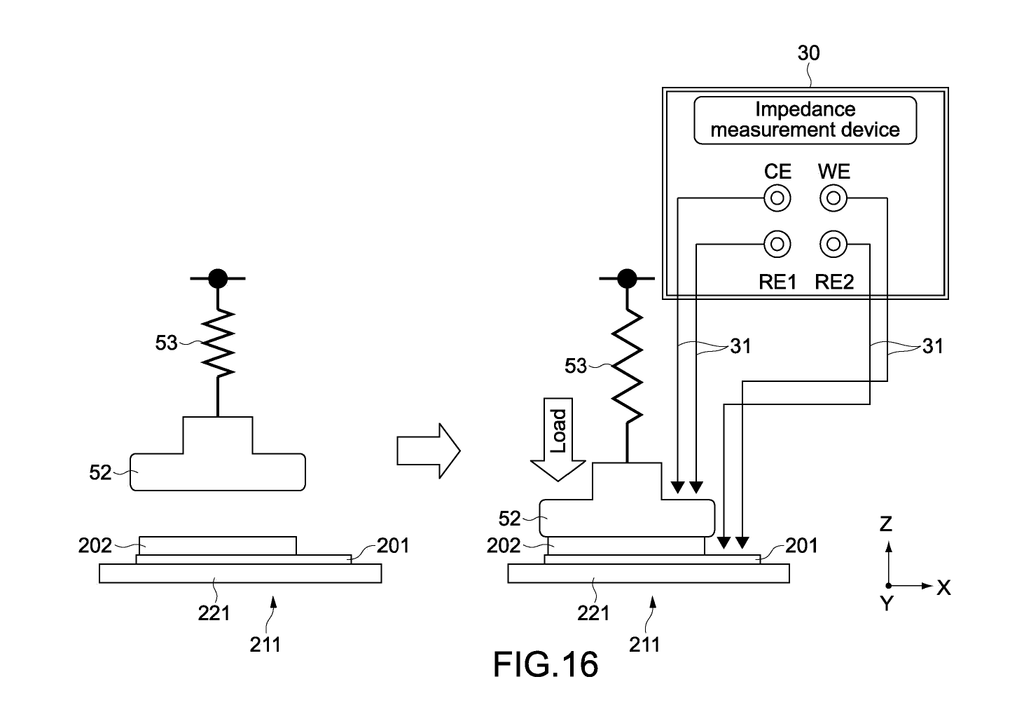

It should be noted that in the descriptions on the fourth embodiment, the dye-sensitized solar cell 200 obtained after one or a plurality of transparent electrode layers 201 and porous semiconductor layers 202 are formed on the transparent substrate 221, is referred to as inspection object 211 (see FIG. 16).

(Electrode Inspection Process)

FIG. 16 is a schematic diagram for explaining the inspection method according to the fourth embodiment of the present disclosure.

As shown in FIG. 16, the inspection object 211 includes the transparent substrate 221 and (one or a plurality of) transparent electrode layers 201 (no sensitizing dye) and porous semiconductor layers 202 formed on the transparent substrate 221.

In the electrode inspection process, the inspection objects 211 are randomly inspected by an operator at a certain interval (e.g., 1 per 100).

The operator applies a load on a conductor 52 that is formed of metal such as aluminum and copper and supported by a spring 53 and brings the conductor 52 into contact with the porous semiconductor layer 202. Then, the operator brings the probes 46 connected to the CE and RE1 terminals of the impedance measurement device 30 into contact with the conductor 52 and also brings the probes 46 connected to the WE and RE2 terminals of the impedance measurement device 30 into contact with the transparent electrode layer 201. As a result, the impedance Z between the transparent electrode layer 201 and the conductor 52 is measured.

The state where the conductor 52 is in contact with the porous semiconductor layer 202 can be regarded as a flat-plate capacitor in which a dielectric body constituted of the porous semiconductor layer 202 is interposed between the transparent electrode layer 201 and the conductor 52. Therefore, the same quality inspection as that of the dye-sensitized solar cell 100 described in the first embodiment becomes possible.

The operator judges whether a difference between the measured impedance Z and the standard impedance Z′ (impedance measured by bringing conductor 52 into contact with porous semiconductor layer 202 of inspection object 211 as non-defective product) is equal to or smaller than a predetermined threshold value. When the difference is equal to or smaller than the predetermined threshold value, the operator judges that the inspection object 211 is a non-defective product. It should be noted that in the fourth embodiment, since the inspection is a destructive inspection due to the conductor 52 being brought into contact with the porous semiconductor layer 202, the inspection object 211 is discarded without being passed on to the subsequent processes even when it is a non-defective product.

On the other hand, when the difference exceeds the predetermined threshold value, the operator judges that the inspection object 211 is a defective product. Then, the operator analyzes a cause of the defect and feeds it back to the previous process (electrode process). The inspection object 211 judged to be a defective product is discarded.

The fourth embodiment bears the same effect as the first embodiment. Specifically, since a quality of the inspection object 211 can be judged in the production process of the dye-sensitized solar cell 200, a quick feedback to the previous process in the production process becomes possible. As a result, generation of a defective product due to process fluctuations can be suppressed, and a yield can be improved. Consequently, cost cut can be realized.

(Dye Adsorption Process to Final Inspection Process)

Referring back to FIG. 15, in a dye adsorption process, the inspection object 211 is immersed in a dye solution. As a result, the sensitizing dye is supported by minute particles of the porous semiconductor layer 202. In the next assembling process, the transparent substrate 221 side and the opposing substrate 222 side are connected. In the next electrolyte injection process, an electrolyte containing a redox pair is injected via an inlet (not shown). After that, the inlet is sealed.

In the next final inspection process, photoelectric conversion characteristics and the like of the dye-sensitized solar cell 200 (finished product) are inspected by sunlight, pseudo sunlight generated by solar simulator, or the like.

The descriptions above have been given on the quality inspection method for the Z-type dye-sensitized solar cell 200. However, qualities of other types of dye-sensitized solar cell 200, such as a W type and a face type, can be inspected during the production process by the same method as that described above.

(Inspection Apparatus)

Although the quality inspection method for the inspection object 211 carried out by the operator has been described in the above example, the quality of the inspection object 211 may be inspected automatically by an inspection apparatus 60.

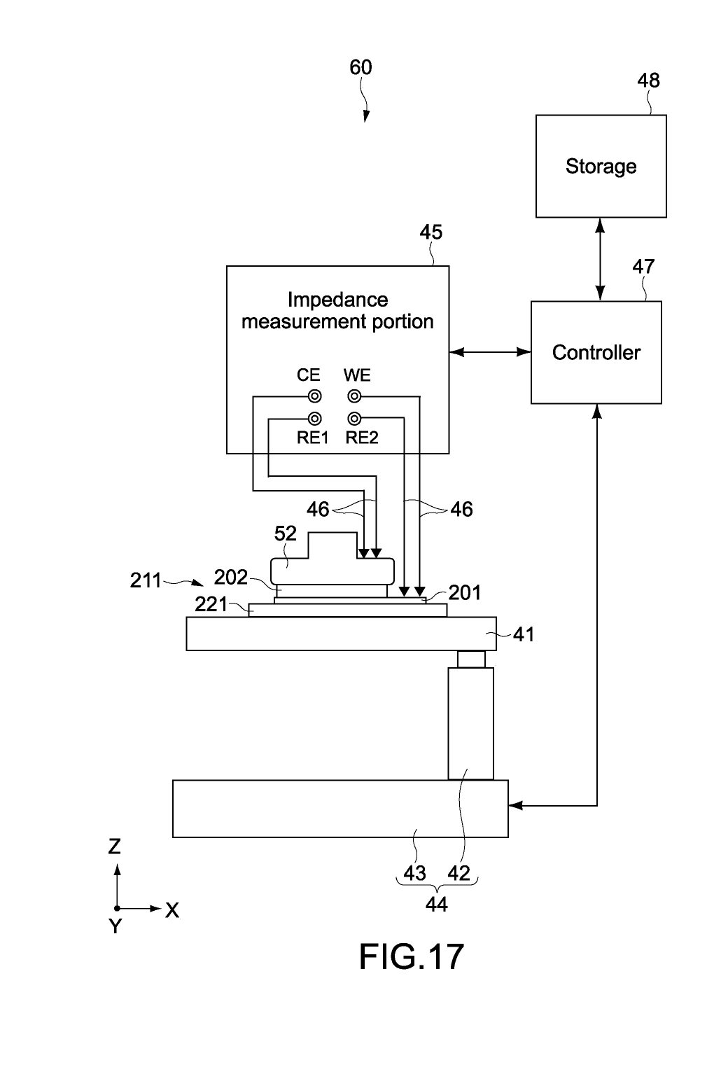

FIG. 17 is a schematic diagram showing the inspection apparatus 60.

The inspection apparatus 60 has the same structure as the inspection apparatus 40 described in the third embodiment (see FIG. 13) except that the conductor 52 is used and that the probes 46 connected to the CE and RE1 terminals of the impedance measurement portion 45 are in contact with the conductor 52.

The conductor 52 and the probes 46 are fixed at predetermined positions by a fixing member (not shown).

The controller 47 of the inspection apparatus 60 drives the XY stage 43 to move the mounting table 41 in the XY directions and moves it to a pick-up position of the inspection object 211. Then, the inspection object 211 is received from a supply apparatus (not shown). Here, the supply apparatus passes the inspection object 211 to the inspection apparatus 40 at certain intervals (e.g., 1 per 100).

Next, the controller 47 drives the XY stage 43 to move the mounting table 41 in the XY directions and moves the inspection object 211 to a measurement position of the impedance Z. Then, the controller 47 drives the lifting mechanism 42 and moves the mounting table 41 upwardly.

When the mounting table 41 is moved upwardly, a bottom surface of the conductor 52 comes into contact with a top surface of the porous semiconductor layer 202. Moreover, the probes 46 connected to the WE and RE2 terminals of the impedance measurement portion 45 come into contact with the transparent electrode layer 201.

Next, the controller 47 controls the impedance measurement portion 45 and measures the impedance Z between the transparent electrode layer 201 of the inspection object 211 and the conductor 52. The controller 47 calculates a difference between the measured impedance Z and the standard impedance Z′ and judges whether the difference is equal to or smaller than a predetermined threshold value. When the difference is equal to or smaller than the predetermined threshold value, the controller 47 judges that the inspection object 211 is a non-defective product, that is, a printing deviation and the like are not caused in the inspection object 211. On the other hand, when the difference exceeds the predetermined threshold value, the controller 47 judges that the inspection object 211 is a defective product, that is, a printing deviation and the like are caused in the inspection object 211.

Upon ending the judgment, the controller 47 stores the judgment result in the storage 48. Then, the controller 47 drives the lifting mechanism 42 and the XY stage 43 and discards the inspection object 211 irrespective of the quality of the inspection object 211.

By the inspection apparatus 60 shown in FIG. 17, the qualities of the Z-type, W-type, and face-type dye-sensitized solar cells 200 can be inspected automatically during the production process.

### Modified Example

The above descriptions have been given on the method of inspecting qualities of the inspection objects 11 and 211 by detecting a defect such as a printing deviation and a short circuit based on the impedances Z of the inspection objects 11 and 211. On the other hand, there is also a method of inspecting qualities of the inspection objects 11 and 211 by measuring the impedances Z of the inspection objects 11 and 211 before the dye adsorption process and after the sensitizing dye adsorption process and judging adsorption amounts of the sensitizing dye of the porous semiconductor layers 2 and 202 from change amounts of the impedances.

In this case, it is also possible for the operator to measure the impedances Z of the inspection objects 11 and 211 before and after the sensitizing dye adsorption process using the impedance measurement device 30 and judge the qualities of the inspection objects 11 and 211 from change amounts of the measurement values. Alternatively, it is also possible to automatically measure the impedances Z of the inspection objects 11 and 211 using the inspection apparatuses 40 and 60 and judge the qualities of the inspection objects 11 and 211 from change amounts of the measurement values.

The present disclosure contains subject matter related to that disclosed in Japanese Priority Patent Application JP 2010-182429 filed in the Japan Patent Office on Aug. 17, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An inspection method, comprising:
measuring an impedance of a cell structure of an inspection object that includes one or a plurality of serially-connected cell structures each including a transparent electrode layer formed on a substrate, a porous semiconductor layer formed on the transparent electrode layer, a porous insulator layer formed on the porous semiconductor layer, and a counter electrode layer formed on the porous insulator layer; and
judging a quality of the inspection object based on the measured impedance of the cell structure.

2. The inspection method according to claim 1,
wherein the judgment on the quality of the inspection object includes comparing a standard impedance as an impedance of the cell structure, that is a criterion for the quality judgment, and the measured impedance of the cell structure, and judge that the inspection object is a non-defective product when a difference between the standard impedance and the impedance is equal to or smaller than a predetermined threshold value.

3. The inspection method according to claim 1,
wherein the measurement of the impedance includes measuring two or more impedances of the cell structure using two or more different frequencies, and
wherein the judgment on the quality of the inspection object includes judging that the inspection object is a non-defective product when a difference between the two or more measured impedances is equal to or larger than a predetermined threshold value.

4. The inspection method according to claim 2,
wherein the measurement of the impedance includes measuring the impedance of the cell structure using a frequency of 10 Hz or more.

5. The inspection method according to claim 4,
wherein the measurement of the impedance includes measuring the impedance of the cell structure using a frequency of 1 kHz or more.

6. The inspection method according to claim 5,
wherein the measurement of the impedance includes measuring the impedance of the cell structure using a frequency that is 1 kHz or more and 1 MHz or less.

7. The inspection method according to claim 6,
wherein the measurement of the impedance includes measuring the impedance of the cell structure using a frequency that is 1 kHz or more and 100 kHz or less.

8. An inspection method, comprising:
bringing a conductor into contact with a porous semiconductor layer of an inspection object including a transparent electrode layer formed on a substrate and the porous semiconductor layer formed on the transparent electrode layer;
measuring an impedance between the transparent electrode layer and the conductor; and
judging a quality of the inspection object based on the measured impedance between the transparent electrode layer and the conductor.

9. An inspection apparatus, comprising:
a measurement portion configured to measure an impedance of a cell structure of an inspection object that includes one or a plurality of serially-connected cell structures each including a transparent electrode layer formed on a substrate, a porous semiconductor layer formed on the transparent electrode layer, a porous insulator layer formed on the porous semiconductor layer, and a counter electrode layer formed on the porous insulator layer; and
a controller configured to judge a quality of the inspection object based on the measured impedance of the cell structure.

10. An inspection apparatus, comprising:
a conductor that is brought into contact with a porous semiconductor layer of an inspection object including a transparent electrode layer formed on a substrate and the porous semiconductor layer formed on the transparent electrode layer;
a measurement portion configured to measure an impedance between the transparent electrode layer and the conductor while the conductor is in contact with the porous semiconductor layer; and
a controller configured to judge a quality of the inspection object based on the measured impedance between the transparent electrode layer and the conductor.

11. An inspection method, comprising:
measuring, by a measurement portion of an inspection apparatus, an impedance of a cell structure of an inspection object that includes one or a plurality of serially-connected cell structures each including a transparent electrode layer formed on a substrate, a porous semiconductor layer formed on the transparent electrode layer, a porous insulator layer formed on the porous semiconductor layer, and a counter electrode layer formed on the porous insulator layer; and
judging, by a controller of the inspection apparatus, a quality of the inspection object based on the measured impedance of the cell structure.

12. An inspection method, comprising:
measuring, by a measurement portion of an inspection apparatus, while a conductor is in contact with a porous semiconductor layer of an inspection object including a transparent electrode layer formed on a substrate and the porous semiconductor layer formed on the transparent electrode layer, an impedance between the transparent electrode layer and the conductor; and
judging, by a controller of the inspection apparatus, a quality of the inspection object based on the measured impedance between the transparent electrode layer and the conductor.
